(19) United States
(12) Patent Application Publication
(10) Pub. No.: US 2012/0243328 A1
(43) Pub. Date: Sep. 27, 2012

(54) NONVOLATILE SEMICONDUCTOR MEMORY DEVICE AND DATA ERASE METHOD OF THE SAME

(75) Inventors: Keiji Tatebe, Yokohama-shi (JP); Takamichi Kasai, Yokohama-shi (JP)

(73) Assignee: KABUSHIKI KAISHA TOSHIBA, Tokyo (JP)

(21) Appl. No.: 13/229,938

(22) Filed: Sep. 12, 2011

(30) Foreign Application Priority Data
Mar. 22, 2011 (JP) 2011-063283

(51) Int. Cl. G11C 16/14

(52) U.S. Cl. 365/185.22

(57) ABSTRACT

According to one embodiment, a nonvolatile semiconductor memory device includes a memory cell array includes a plurality of pages formed in a common semiconductor region, each of the pages includes a plurality of electrically programmable memory cells, a control circuit configured to performs an erase operation for a selected page, and a verification circuit configured to verify a threshold value of the memory cell array after the erase operation. The verification circuit uses a first erase verification voltage when verifying the selected page, and a second erase verification voltage different from the first erase verification voltage when verifying an unselected page.

### CROSS-REFERENCE TO RELATED APPLICATIONS

This application is based upon and claims the benefit of priority from prior Japanese Patent Application No. 2011-063283, filed Mar. 22, 2011, the entire contents of which are incorporated herein by reference.

### FIELD

Embodiments described herein relate generally to a nonvolatile semiconductor memory device and a data erase method of the same.

### BACKGROUND

A NOR flash memory is known as a kind of nonvolatile semiconductor memory device. This NOR flash memory is often used in portable devices and IC cards.

The NOR flash memory can erase data for each block including a plurality of memory cells. In a data write operation (an operation of injecting electrons in a memory cell) of the NOR flash memory, data can be written for each bit by applying a voltage by designating a bit line and word line. In an actual product, a plurality of bits are sometimes written at the same time in order to increase the write speed. In contrast, in a data erase operation (an operation of extracting electrons from a memory cell), data of a block having a common well region are simultaneously erased by applying a bias to a word line and the well region.

In this simultaneous block erase operation, the voltage applied to the word line and well region is constant. In practice, memory cells have variations in various dimensions and film thickness. Therefore, an excessively erased memory cell (overerased cell) is produced at the end of the simultaneous block erase operation. This overerased cell has a large leakage current and hence causes a read or write error.

### BRIEF DESCRIPTION OF THE DRAWINGS

FIG. 1 is a block diagram of a NOR flash memory according to an embodiment;

FIG. 2 is a circuit diagram of a memory cell array;

FIG. 3 is a plan view of the memory cell array;

FIGS. 4A and 4B are exemplary views for explaining the erase operation and write operation of a memory cell;

FIG. 5 is a graph for explaining the threshold voltage distribution of a memory cell;

FIG. 6 is a flowchart showing the erase operation of a NOR flash memory 10;

FIGS. 7A, 7B, 7C, 7D, and 7E are graphs for explaining the change in memory cell threshold voltage in the erase operation; and

FIG. 8 is a view for explaining disturbance of an unselected page.

### DETAILED DESCRIPTION

In general, according to one embodiment, there is provided a nonvolatile semiconductor memory device comprising:

a memory cell array comprising a plurality of pages formed in a common semiconductor region, each of the pages comprising a plurality of electrically programmable memory cells;

a control circuit configured to performs an erase operation for a selected page; and

a verification circuit configured to verify a threshold value of the memory cell array after the erase operation,

wherein the verification circuit uses a first erase verification voltage when verifying the selected page, and a second erase verification voltage different from the first erase verification voltage when verifying an unselected page.

The embodiments will be described hereinafter with reference to the accompanying drawings. In the description which follows, the same or functionally equivalent elements are denoted by the same reference numerals, to thereby simplify the description.

### [1. Structure of Nonvolatile Semiconductor Memory Device]

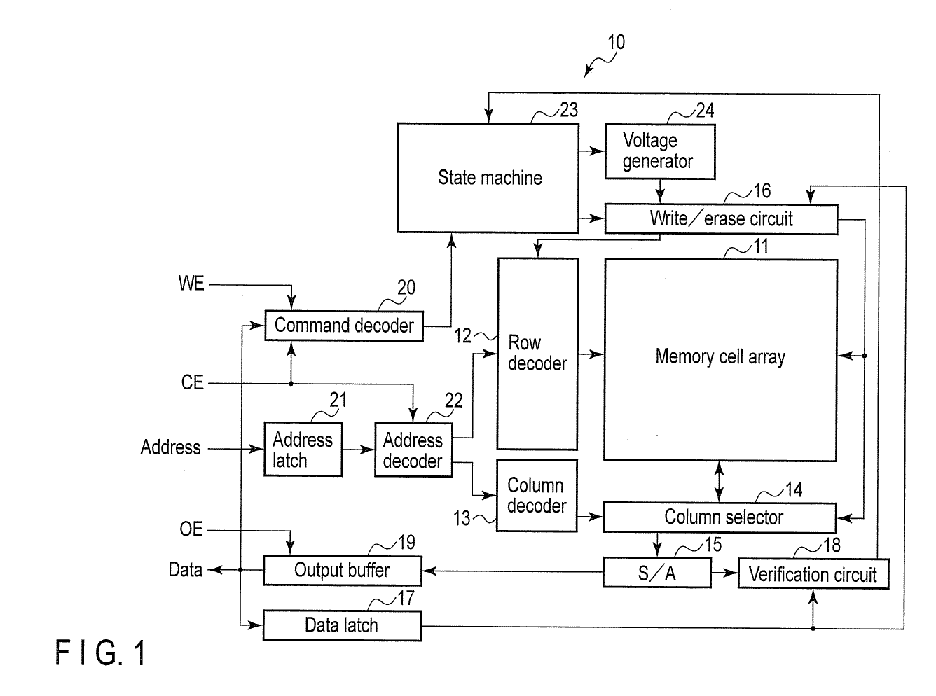

A NOR flash memory will be explained below as an example of a nonvolatile semiconductor memory device. FIG. 1 is a block diagram of a NOR flash memory 10 according to an embodiment.

A memory cell array 11 includes a plurality of NOR flash memory cells arranged in a matrix. Each memory cell is connected to a bit line, word line, and source line.

A row decoder 12 is connected to word lines, and selects a word line based on a row address. Also, the row decoder 12 applies predetermined voltages to word lines in an erase operation, write operation, and read operation.

A column decoder 13 selects a bit line based on a column address, and generates a column select signal for selecting a bit line. This column select signal is supplied to a column selector 14. The column selector 14 selects a bit line based on the column select signal, and connects the bit line to a sense amplifier (S/A) 15 or write/erase circuit 16. The sense amplifier 15 senses and amplifies data read from the memory cell array 11.

The write/erase circuit 16 writes data to a predetermined memory cell unit (page) at once. Also, the write/erase circuit 16 erases data from a predetermined memory cell unit (block or page). In the write operation and erase operation, the write/erase circuit 16 controls the voltages of a bit line, a word line, the source line, and a well in which a memory cell is formed.

A data latch 17 receives externally supplied write data, and holds this write data. The write data held in the data latch 17 is supplied to the write/erase circuit 16 and a verification circuit 18.

In the write operation, the verification circuit 18 performs a verification operation by using the write data supplied from the data latch 17 and data read from the sense amplifier 15. In the erase operation, the verification circuit 18 determines (verifies) whether data read from the sense amplifier 15 is data indicating an erased state. The verification circuit 18 supplies the verification result to a state machine (control circuit) 23.

An output buffer 19 receives an output enable signal OE from an external device. If the output enable signal OE is asserted (for example, made high), the output buffer 19 outputs read data supplied from the sense amplifier 15 to the external device. A command decoder 20 receives a chip enable signal CE and write enable signal WE from an external device. If both the chip enable signal CE and write enable signal WE are asserted (for example, made high), the command decoder 20 receives a command input from the external device. The command decoder 20 interprets the command and supplies a command signal to the state machine 23.

An address latch 21 receives an externally supplied address and holds it. An address decoder 22 receives an externally supplied chip enable signal CE, and receives an address from the address latch 21. If the chip enable signal CE is asserted, the address decoder 22 decodes the address, and supplies a row address to the row decoder 12 and a column address to the column decoder 13.

A voltage generator 24 generates various voltages necessary for the erase, write, read, and verification operations by using a power supply voltage VDD and ground voltage VSS applied from outside.

The state machine (control circuit) 23 controls each module in the NOR flash memory 10. That is, the state machine 23 controls the erase, write, read, and verification operations by controlling the state of each module in the NOR flash memory 10. Note that the state machine 23 supplies control signals to, for example, the sense amplifier 15 and verification circuit 18 as well. However, the block diagram does not show these control signal lines in order to avoid the complication of the diagram.

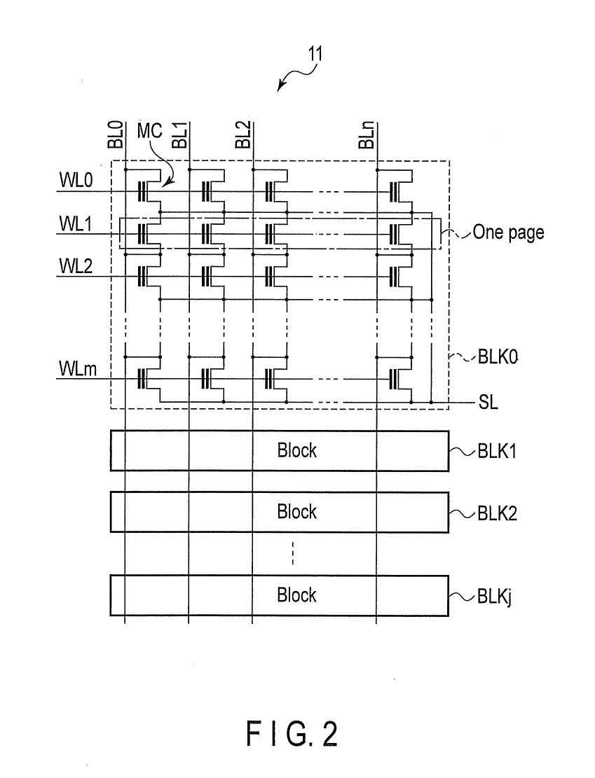

Next, the arrangement of the memory cell array 11 will be explained. FIG. 2 is a circuit diagram of the memory cell array 11. The memory cell array 11 includes (j+1) (j is an integer of 0 or more) blocks BLK0 to BLKj. Each block BLK includes ((m+1)×(n+1)) (m and n are integers of 1 or more) memory cells MC. Each memory cell MC is a MOSFET including a stacked gate including a charge storage layer (for example, a floating gate electrode) formed on a gate insulating film on the well, and a control gate electrode formed on an inter-gate insulating film on the floating gate electrode.

The control gate electrodes of memory cells MC on the same row are connected together to one of word lines WL0 to WLm. The drains of memory cells MC in the same column are connected together to one of bit lines BL0 to BLn. The sources of the memory cells MC are connected together to the same source line SL. A set of (n+1) memory cells MC connected to the same word line will be called a page. Note that a page need only be a set of a plurality of memory cells connected to the same word line. In this embodiment, however, a set of (n+1) memory cells is defined as a page for the sake of descriptive simplicity. A page is a minimum unit for data write and data erase. Also, a plurality of pages form the block BLK as a unit. The block BLK includes a memory cells sharing the well, and is the unit of data erase. That is, in this embodiment, data of the memory cell array 11 can be erased for each block BLK or each page. The bit lines BL0 to BLn are connected together to the blocks BLK0 to BLKj.

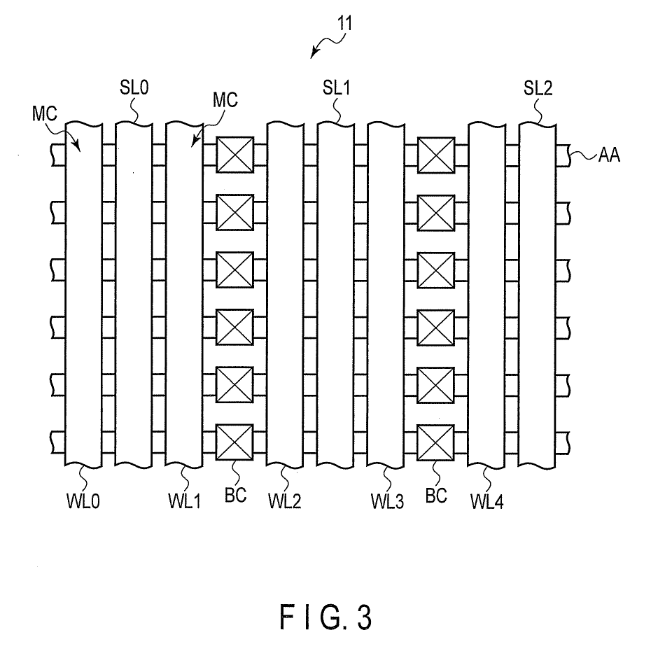

FIG. 3 is a plan view of the memory cell array 11. Word lines WL0 to WL4 run in the row direction. A plurality of active areas AA are formed to cross the word lines WL. The memory cells MC are formed in regions where the word lines WL and active areas AA intersect each other. Source lines SL0 to SL2 are formed parallel to the word lines. Source lines SL0 to SL2 are electrically connected to each other. Source line SL0 is placed between word lines WL0 and WL1. Source line SL1 is placed between word lines WL2 and WL3. Source line SL0 is electrically connected to the source region between word lines WL0 and WL1 via a contact plug. Likewise, source line SL1 is electrically connected to the source region between word lines WL2 and WL3 via a contact plug. Bit line contact plugs BC are formed on the drain region between word lines WL1 and WL2, and the drain region between word lines WL3 and WL4. The bit line contact plugs BC are connected to the bit lines BL (not shown).

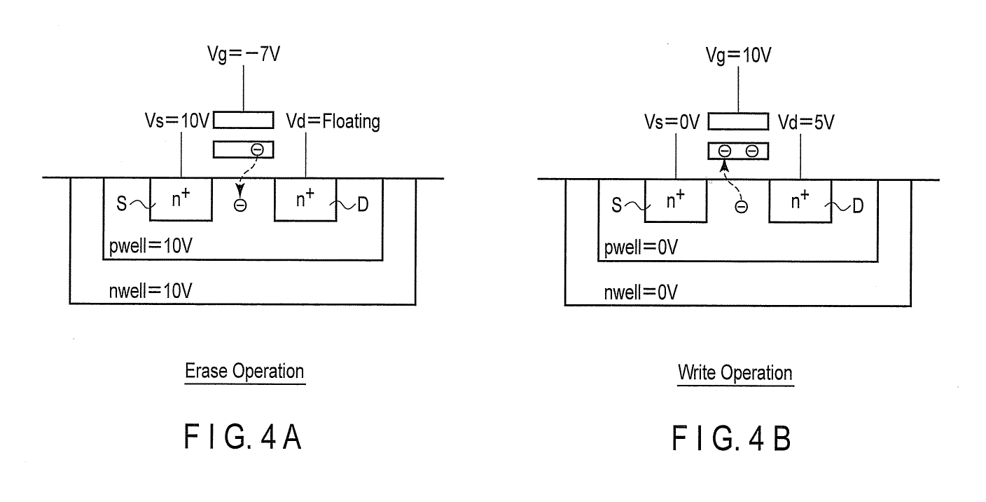

FIGS. 4A and 4B are exemplary views for explaining the erase operation and write operation of the memory cell MC. An n-type well is formed in a p-type semiconductor substrate (not shown), a p-type well is formed in the n-type well, and the memory cell MC is formed in this p-type well. One block BLK is formed in one p-type well, and the plurality of blocks BLK are electrically isolated by the n-type well.

The memory cell MC includes a source region S and drain region D formed apart from each other in the p-type well, and a stacked gate formed on the p-type well between the source region S and drain region D, and including a floating gate electrode and control gate electrode. The source region S and drain region D are made of n+-type diffusion regions formed by heavily doping an n-type impurity in the p-type well.

The erase operation of the memory cell MC is performed by the FN tunneling method. As shown in FIG. 4A, the write/erase circuit 16 performs voltage control such that a control gate voltage Vg of the memory cell MC is set to, for example, −7 V, a source voltage Vs is set to, for example, 10 V, and the drain is made to float. Also, the write/erase circuit 16 applies, for example, 10 V to the n-type well and p-type well. Consequently, a high electric field of 17 V is applied to a tunnel insulating film, and electrons are extracted from the floating gate electrode by the FN tunneling phenomenon. Since the floating gate electrode has almost no electrons in this state, a cell threshold voltage Vth decreases. When a read voltage (for example, 5 V) is applied to the control gate electrode of the memory cell MC, therefore, the memory cell MC is turned on (erased). This erased state is defined as binary 1.

The write operation of the memory cell is performed by the channel hot electron (CHE) method. As shown in FIG. 4B, the write/erase circuit 16 performs voltage control such that the control gate voltage Vg of a selected memory cell is set to, for example, 10 V, the source voltage Vs is set to zero, and a drain voltage Vd is set to, for example, 5 V. Also, the write/erase circuit 16 applies 0 V to the n-type well and p-type well. Consequently, hot electrons generated near the drain are injected into the floating gate electrode. In this state, the electrons injected into the floating gate electrode raise the cell threshold voltage Vth. When a read voltage (for example, 5 V) is applied to the control gate electrode of the memory cell MC, therefore, the memory cell MC is turned off (written). This written state is defined as binary 0.

The read operation of the memory cell is performed as follows. The sense amplifier 15 charges a bit line BL selected by the column address to, for example, 1 V. A zero voltage is applied to the source line SL. After that, the row decoder 12 applies, for example, 5 V to a word line WL selected by the row address. Consequently, a current flows from the bit line BL to the source line SL via the memory cell if the memory cell is in the erased state, and no current flows from the bit line BL to the source line SL via the memory cell if the memory cell is in the written state. The sense amplifier 15 senses and amplifies this current, thereby reading binary 0 or 1.

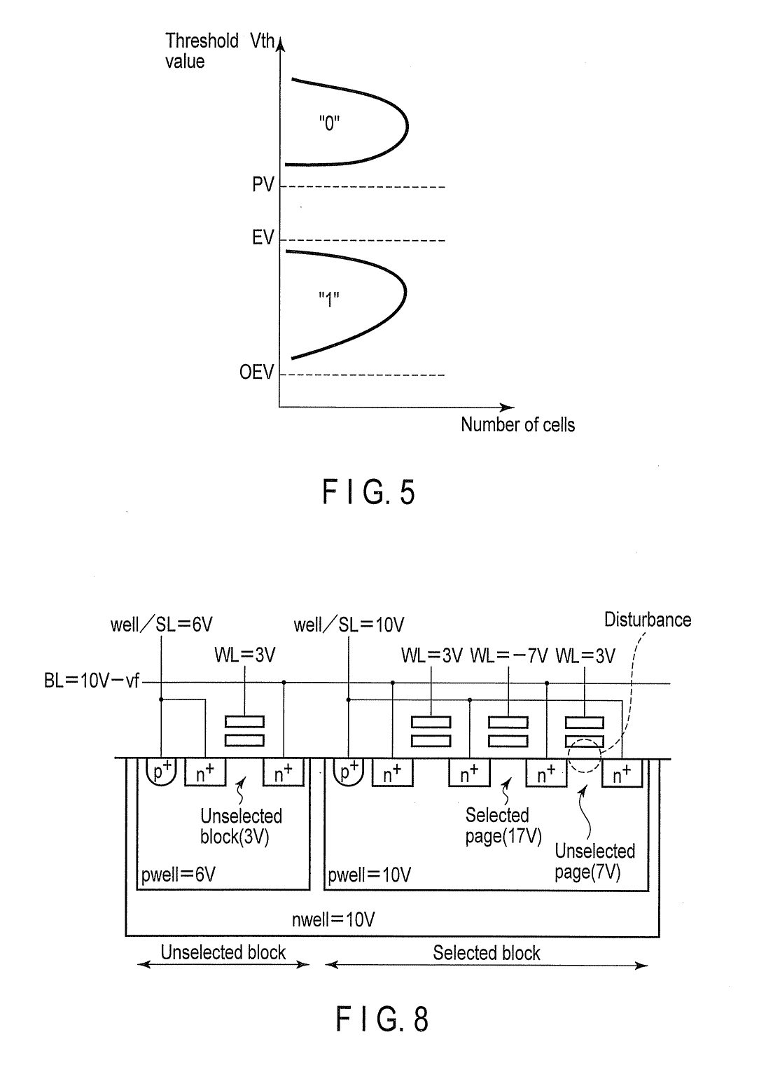

FIG. 5 is a graph for explaining the threshold voltage distribution of the memory cell MC. The threshold voltage Vth of a memory cell in the erased state is set to fall within a predetermined voltage distribution by repeating the erase operation and verification operation. Similarly, the threshold voltage Vth of a memory cell in the written state is set to fall within a predetermined voltage distribution by repeating the write operation and verification operation.

The threshold voltage of a memory cell in the erased state is set between an overerase verification voltage OEV and erase verification voltage EV. The threshold voltage of a memory cell in the written state is set to be greater than or equal to a write verification voltage PV. Accordingly, when a read voltage greater than or equal to the erase verification voltage EV and less than or equal to the write verification voltage PV is applied to a word line, a memory cell in the erased state is turned on, and a memory cell in the written state is turned off. This makes it possible to discriminate data of the memory cell.

### [2. Operation]

The operation of the NOR flash memory 10 configured as described above will be explained below. In this embodiment, when erasing data of the memory cell array 11, the erase operation can be performed for each block or each page. Since an erase operation performed for each block is the same as a general erase operation, an erase operation performed for each page will be explained below. A page as an erase target will be called a selected page, and a block including the selected page will be called a selected block.

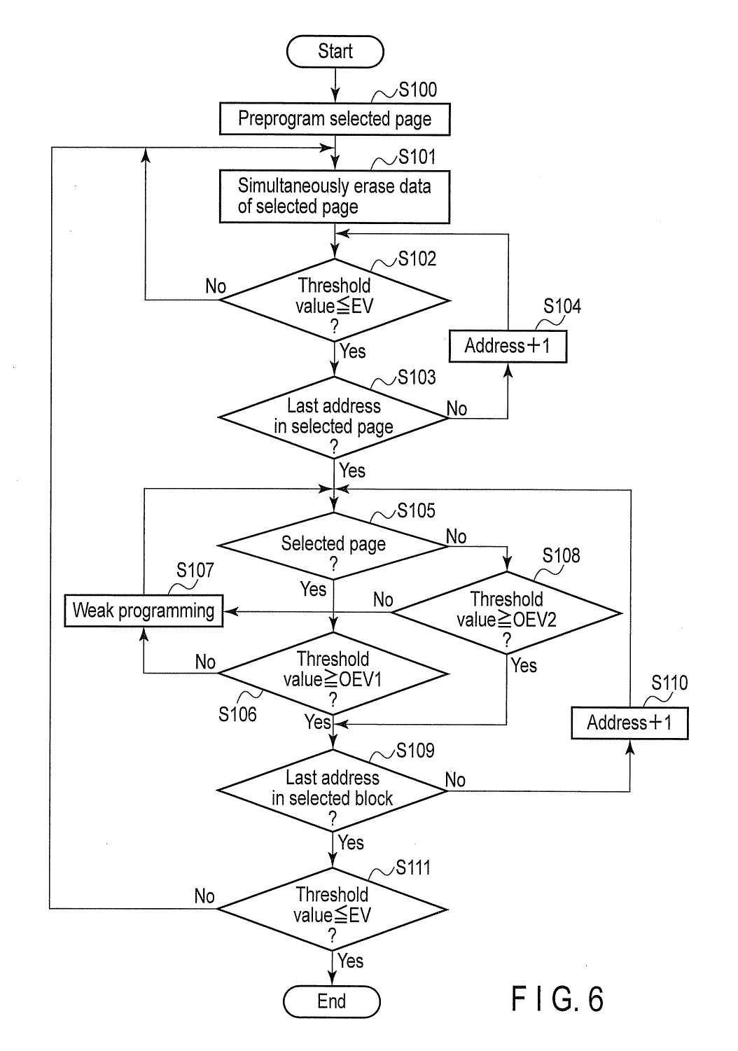

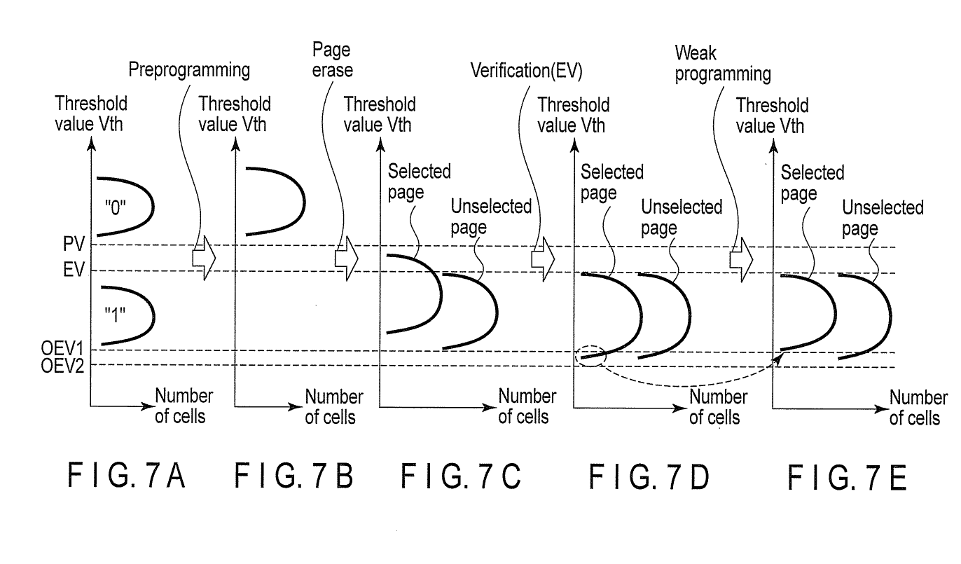

FIG. 6 is a flowchart showing the erase operation of the NOR flash memory 10. FIGS. 7A, 7B, 7C, 7D, and 7E are graphs showing the change in memory cell threshold voltage in the erase operation.

FIG. 7A is a graph for explaining the threshold voltage distribution of a selected page before erase. Before erase, binary 1's (erased state) and 0's (written state) exist at random in the selected page. First, the state machine 23 writes all memory cells in the selected page to a voltage greater than or equal to a given threshold voltage (step S100). This operation is called preprogramming. If binary 1's (erased state) and 0's (written state) exist at random in memory cells of the selected page (i.e., if the memory cell threshold voltage varies), an overerased or undererased memory cell exists after simultaneous erase, and the variation in threshold voltage increases after erase. Therefore, preprogramming is performed in order to arrange the threshold voltages at the same start point before erase.

This preprogramming operation is the same as the write operation. That is, the state machine 23 applies the voltages shown in FIG. 4B to all memory cells in the selected page. FIG. 7B shows a threshold voltage distribution after preprogramming. As shown in FIG. 7B, the threshold voltages of all memory cells in the selected page are shifted to, for example, the written state. Note that the threshold voltage set by preprogramming need not be the same as the written state, and can freely be set.

Subsequently, the state machine 23 simultaneously erases data of the selected page (step S101). That is, the state machine 23 applies a voltage VBB (for example, −7 V) to a selected word line, a voltage VDDH (for example, 10 V) to the source line, and voltage VDDH to the p-type well and n-type well, thereby making all bit lines float. FIG. 7C shows a threshold voltage distribution after, for example, the first page erase. FIG. 7C also shows the threshold voltage distribution of memory cells in the erased state in an unselected page. Note that in FIG. 7C, the threshold voltage distribution of the unselected page is shifted to the right from that of the selected page in order to make the drawing easy to understand. This similarly applies to FIGS. 7D and 7E.

Then, the sense amplifier 15 and verification circuit 18 determine (verify) whether the threshold voltages of all memory cells in the selected page are less than or equal to the erase verification voltage EV (step S102). This verification operation is performed for each memory cell (steps S103 and S104). That is, the state machine 23 repeats the verification operation using the erase verification voltage EV for each memory cell while incrementing the address by one at a time until the last address in the selected page. If a memory cell that has not passed verification exists in step S102, the erase operation is performed again. FIG. 7D shows a threshold voltage distribution after verification using the erase verification voltage EV.

Since this embodiment performs page erase, disturbance occurs in an unselected page in the same block (selected block) as that of a selected page. FIG. 8 is a view for explaining the disturbance of the unselected page.

When simultaneously erasing data of a selected page, it is necessary to prevent data of an unselected page from being erased. Therefore, an unselected gate voltage VDDL (for example, 3 V) is applied to a word line of the unselected page. Consequently, a voltage of 17 V is applied across the control gate electrode and well in the selected page, and a voltage of 7 V is applied across the control gate electrode and well in the unselected page. Also, in an unselected block, the unselected gate voltage VDDL is applied to all word lines, and a voltage of, for example, 6 V is applied to the source line and p-type well. Since the bit line is floating, it is set to a voltage 10 V—vf where vf is the voltage drop of a p-n junction. In the unselected block, therefore, a voltage of 3 V is applied across the control gate electrode and well. The voltage control as described above prevents data of the unselected page and unselected block from being erased.

As described previously, however, a voltage of 7 V is applied across the control gate electrode and well in the unselected page, so electrons may be extracted from memory cells of the unselected page. Consequently, memory cells in the erased state of the unselected page are overerased. As shown in FIG. 7D, when verification using the erase verification voltage EV is complete, the threshold voltages of some memory cells in the unselected page that is not an erase target are lower than an overerase verification voltage OEV1. In this embodiment, therefore, as will be described later, the overerase verification voltage for use in overerase verification of a selected page is made different from that for use in overerase verification of an unselected page.

The state machine 23 performs the overerase verification operation for all memory cells in the selected block. This overerase verification is performed for each memory cell. That is, the state machine 23 determines whether the selected page includes a memory cell as an overerase verification target (step S105). If the selected page includes a memory cell as an overerase verification target, the sense amplifier 15 and verification circuit 18 verify whether the threshold voltages of all memory cells in the selected page are greater than or equal to overerase verification voltage OEV1 (step S106).

For a memory cell that has not passed overerase verification in step S106, the state machine 23 performs weak programming (step S107). This weak programming is not an operation of applying a high voltage VDDH (for example, 10 V) to be written as binary 0 to the gate and drain of the memory cell, but an operation of applying a voltage lower than voltage VDDH to the gate and drain of the memory cell, and decreases the shift width of the threshold voltage of the memory cell when compared to a normal write operation. The drain voltage, source voltage, and well voltage of weak programming are the same as those of the write operation.

On the other hand, if the unselected page includes a memory cell as an overerase verification target in step S105, the sense amplifier 15 and verification circuit 18 verify whether the threshold voltages of all memory cells in the unselected page are greater than or equal to an overerase verification voltage OEV2 (step S108). Voltage OEV2 is set lower than voltage OEV1. However, if voltage OEV2 is too low, the number of memory cells having low threshold voltages increases, and the leakage current increases. Therefore, an appropriate voltage OEV2 is set so as not to increase the leakage current of a memory cell. For a memory cell that has not passed overerase verification in step S108, the state machine 23 performs weak programming (step S107). Thus, for a memory cell whose threshold voltage has become greater than or equal to overerase verification voltage OEV2 and lower than overerase verification voltage OEV1 due to disturbance in the unselected page, the verification operation is performed by using overerase verification voltage OEV2, so this memory cell is not a target of weak programming.

Subsequently, the state machine 23 executes the overerase verification operation using overerase verification voltages OEV1 and OEV2 for each of all memory cells in the selected block (steps S109 and S110). That is, the state machine 23 repeats the overerase verification operation using overerase verification voltages OEV1 and OEV2 for each memory cell while incrementing the address by one at a time until the last address in the selected block.

FIG. 7E shows a threshold voltage distribution after this overerase verification. The threshold voltages of all memory cells in the selected page are set greater than or equal to overerase verification voltage OEV1. The threshold voltage of a memory cell holding binary 1 (a memory cell in the erased state) in the unselected page is set greater than or equal to overerase verification voltage OEV2. Although not shown in FIG. 7E, a memory cell in the written state in the unselected page naturally has a threshold voltage greater than or equal to overerase verification voltage OEV2.

Then, the sense amplifier 15 and verification circuit 18 verify whether the threshold voltages of all memory cells in the selected page are greater than or equal to the erase verification voltage EV again (step S111). If all memory cells in the selected page have passed erase verification, the erase operation is complete. If a memory cell that has not passed erase verification exists among all memory cells in the selected page, the process returns to step S101, and the erase operation is repeated.

### [3. Effects]

In this embodiment as has been explained in detail above, the NOR flash memory 10 can perform the erase operation for each page, and, after the erase operation of a selected page, performs the overerase verification operation for an entire selected block including the selected page. The overerase verification operation is performed using overerase verification voltage OEV1 for memory cells included in the selected page, and performed using overerase verification voltage OEV2 lower than overerase verification voltage OEV1 for memory cells included in an unselected page.

If the verification operation is performed using only overerase verification voltage OEV1 for a selected block, disturbance increases the number of memory cells having threshold voltages lower than overerase verification voltage OEV1 in an unselected page. Consequently, the number of memory cells that do not pass overerase verification increases, and the time required for the weak programming process is prolonged. Especially when the block capacity increases, the time necessary for the weak programming process is further prolonged, and the total erase time is prolonged.

In this embodiment as described previously, however, the verification operation is performed for an unselected page by using overerase verification voltage OEV2 lower than overerase verification voltage OEV1. Therefore, the number of memory cells as targets of the weak programming process can be decreased. This makes it possible to shorten the total erase time including the verification operation.

Also, this embodiment executes the step of performing erase verification by using the erase verification voltage EV, the step of performing overerase verification by using overerase verification voltage OEV1, the step of performing overerase verification by using overerase verification voltage OEV2, and the step of performing erase verification by using the erase verification voltage EV again. Accordingly, the threshold voltage in a selected block can accurately be controlled when the series of erase operations are complete. This makes it possible to reduce variations in threshold voltages of memory cells in the erased state.

In addition, the threshold voltage distribution of memory cells in the erased state can be narrowed by controlling the overerase verification voltage OEV. Since this can reduce the bit line off leakage current, the performance of the read and write operations can be improved.

Furthermore, the memory cell threshold voltage distribution can be narrowed and hence can be lowered as a whole. This can reduce the power consumption of the NOR flash memory 10 by lowering the read gate voltage and the threshold voltage after write.

Note that it is also possible to simultaneously erase data of a plurality of pages (smaller than a block) in a selected block. In this case, after steps S100 to S103 in FIG. 6 are repeated for the plurality of pages, the overerase verification operations using OEV1 and OEV2 are collectively performed for the plurality of pages. Since this can shorten the time required for the verification operation, the erase time can be shortened.

It is also possible to perform overerase verification in a selected block for only memory cells in the erased state.

In this embodiment, a memory cell for storing binary values (one-bit data) has been explained for the sake of simplicity. However, this embodiment is also applicable even when using a memory cell capable of storing multilevel values more than binary values (data having two or more bits).

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A nonvolatile semiconductor memory device comprising:
a memory cell array comprising a plurality of pages formed in a common semiconductor region, each of the pages comprising a plurality of electrically programmable memory cells;
a control circuit configured to performs an erase operation for a selected page; and
a verification circuit configured to verify a threshold value of the memory cell array after the erase operation,
wherein the verification circuit uses a first erase verification voltage when verifying the selected page, and a second erase verification voltage different from the first erase verification voltage when verifying an unselected page.

2. The device of claim 1, wherein the second erase verification voltage is lower than the first erase verification voltage.

3. The device of claim 1, wherein the verification circuit determines whether a threshold value of the selected page is not less than the first erase verification voltage, and determines whether a threshold voltage of the unselected page is not less than the second erase verification voltage.

4. The device of claim 1, wherein
the control circuit performs the erase operation for each page, and
the verification circuit performs the verification operation for the memory cell array.

5. The device of claim 1, wherein the control circuit performs a first write operation of raising a threshold value of a memory cell which does not pass verification in the memory cell array.

6. The device of claim 5, wherein
the control circuit performs the first write operation by using a first write voltage, and
the first write voltage is lower than a second write voltage to be used when setting a memory cell in a written state.

7. The device of claim 1, wherein in the erase operation, the control circuit applies a negative erase voltage to the selected page, and a voltage higher than the erase voltage to the unselected page.

8. The device of claim 1, wherein before the erase operation, the control circuit sets a threshold value of the selected page at a level not less than a predetermined level.

9. The device of claim 1, wherein the memory cell comprises a stacked gate including a charge storage layer.

10. A data erase method of a nonvolatile semiconductor memory device,
the nonvolatile semiconductor memory device comprising a memory cell array comprising a plurality of pages formed in a common semiconductor region, each of the pages comprising a plurality of electrically programmable memory cells,
the method comprising:
performing an erase operation for a selected page;
verifying, after the erase operation, a threshold value of the selected page by using a first erase verification voltage; and
verifying, after the erase operation, a threshold value of an unselected page by using a second erase verification voltage different from the first erase verification voltage.

11. The method of claim 10, wherein the second erase verification voltage is lower than the first erase verification voltage.

12. The method of claim 10, wherein
the verification of the selected page comprises determining whether the threshold value of the selected page is not less than the first erase verification voltage, and
the verification of the unselected page comprises determining whether the threshold value of the unselected page is not less than the second erase verification voltage.

13. The method of claim 10, wherein
the erase operation is performed for each page, and
the verification operation is performed for the memory cell array.

14. The method of claim 10, further comprising raising a threshold value of a memory cell which does not pass verification in the memory cell array.

15. The method of claim 14, wherein
the raising the threshold value comprises applying a first write voltage to the memory cell, and
the first write voltage is lower than a second write voltage to be used when setting a memory cell in a written state.

16. The method of claim 10, wherein the performing the erase operation comprises applying a negative erase voltage to the selected page, and applying a voltage higher than the erase voltage to the unselected page.

17. The method of claim 10, further comprising setting, before the erase operation, the threshold value of the selected page at a level not less than a predetermined level.

18. The method of claim 10, wherein the memory cell comprises a stacked gate including a charge storage layer.
